(19) United States
(12) Patent Application Publication
(10) Pub. No.: US 2003/0151149 A1
(43) Pub. Date: Aug. 14, 2003

(54) Semiconductor device

(75) Inventor: Takashi Ichikawa, Hyogo (JP)

Correspondence Address: McDERMOTT, WILL & EMERY, 600 13th Street, N.W., Washington, DC, 20005-3096, US

(73) Assignee: Mitsubishi Denki Kabushiki Kaisha

(21) Appl. No.: 10/214,574

(22) Filed: Aug. 9, 2002

(30) Foreign Application Priority Data
Feb. 13, 2002 (JP) 2002-035683(P)

(51) Int. Cl. H01L 23/48

(52) U.S. Cl. 257/784

(57) ABSTRACT

A semiconductor device of the present invention is provided with a bonding pad for connecting a gold wire which serves as a bonding wire. Bonding pad is formed on a flat surface of an insulating layer, and has a plurality of recesses in a connection region of bonding pad to which a ball portion is connected. Thereby, it is possible to obtain a semiconductor device which has a bonding pad having excellent bonding characteristics with a simple manufacturing process.

### BACKGROUND OF THE INVENTION

1. Field of the Invention

The present invention relates to a semiconductor device, and more specifically to a semiconductor device provided with a bonding pad for connecting a bonding wire.

2. Description of the Background Art

A bonding pad for connecting a bonding wire is conventionally formed of a metal film, such as of aluminum (Al), in a semiconductor device. The tip of a gold wire in a ball form is pressed onto such a bonding pad so that an interdiffusion layer is formed in the connection part by means of ultrasonic waves and heat and, thereby, the bonding wire is electrically and physically connected to the bonding pad. In the following, a semiconductor device provided with a conventional bonding pad is concretely described.

FIGS. 12 and 13 are a cross sectional view and a plan view schematically showing the configuration of a semiconductor device provided with a conventional bonding pad. Here, FIG. 12 is a schematic cross sectional view along line XII-XII in FIG. 13.

In reference to FIGS. 12 and 13, a semiconductor device 101 has a semiconductor element 102 made of silicon, or the like, a bonding pad (pad for wiring) 104 formed above the top surface of this semiconductor element 102 via an insulating layer 103 and a gold wire (bonding wire) 105 that is electrically connected to this bonding pad 104. The tip of gold wire 105, which is connected to bonding pad 104, becomes a ball portion 106 formed by spark discharge, or the like. An interdiffusion region 107 is formed, by means of ultrasonic waves or heat, at the junction interface of this ball portion 106 with bonding pad 104. This interdiffusion region 107 physically and electrically connects gold wire 105 to bonding pad 104.

In order to make a junction between such a bonding pad 104 and ball portion 106 of gold wire 105, first, ball portion 106 is pressed from above by a capillary head against the top surface of bonding pad 104. Then, interdiffusion region 107 is formed under heat conditions of a temperature from 200° C. to 300° C. by utilizing intermetallic diffusion between ball portion 106 and bonding pad 104 and, thereby, thermo-compression bonding is carried out. Ultrasonic waves may be applied together with this thermo-compression bonding so that the intermetallic diffusion is accelerated.

In such a connection method the compressively bonded portion between ball portion 106 and bonding pad 104 is biased to the outer peripheral portion (for example, the hatched region) of ball portion 106, as shown in FIG. 14. In addition, interdiffusion region 107 is formed by means of ultrasonic wave thermo-compression bonding and, therefore, in some cases, interdiffusion region 107 is not created when the power of the ultrasonic waves is insufficient.

The greater is the frictional force between ball portion 106 and bonding pad 104 generated by ultrasonic waves at the time of wire bonding, the more easily the above described interdiffusion region 107 tends to be formed. In the above described prior art, however, the top surface of bonding pad 104 is a plane and, therefore, the frictional force between ball portion 106 and bonding pad 104 generated by ultrasonic waves at the time of wire bonding becomes small. Therefore, interdiffusion region 107 is not effectively formed between ball portion 106 and bonding pad 104. Accordingly, a problem sporadically arises wherein ball portion 106 peels off from bonding pad 104 during the manufacturing process or during utilization of the completed product.

A method for forming a bonding pad, of which the bonding force is enhanced, is described in, for example, Japanese Patent Laying-Open No. 57-23247 (1982). FIGS. 15 to 18 are schematic cross sectional views showing, in the order of the steps, a manufacturing method for a bonding pad described in Japanese Patent Laying-Open No. 57-23247 (1982).

In reference to FIG. 15, an SiO₂ layer 203 is formed on a semiconductor substrate 202 and selective etching is carried out on this SiO₂ layer 203. Thereby, recesses 203a, in a striped pattern, are created in SiO₂ layer 203.

In reference to FIG. 16, an SiO₂ layer is again formed on SiO₂ layer 203. Thereby, recesses 203b in a striped pattern corresponding to the form of recesses 203a in the stripped pattern are created on the surface of SiO₂ layer 203.

In reference to FIG. 17, an Al layer 204 is deposited on SiO₂ layer 203. Unevenness corresponding to the unevenness on the top surface of SiO₂ layer 203 is implemented on the bonding pad portion of this Al layer 204.

In reference to FIG. 18, wire bonding is carried out on the bonding pad portion of Al layer 204 having the unevenness. Thereby, a bonding wire 205 is electrically connected to Al layer 204.

This publication describes that unevenness is provided on the bonding pad portion of Al layer 204 and, therefore, sufficient bonding force can be gained between bonding wire 205 and Al layer 204.

In order to provide unevenness in the bonding pad, however, it is necessary to provide steps in SiO₂ layer 203, which is the base, and there is a problem wherein the manufacturing process becomes complex.

In addition, Al layer 204 is usually formed by means of a sputtering method, which has poor step coverage. Therefore, in the case that SiO₂ layer 203 has unevenness, Al layer 204 is thickly formed on the surface of SiO₂ layer 203 except within each recess and is thinly formed on the bottom of each recess as shown in FIG. 19. Therefore, bonding wire 205 formed on this Al layer 204 cannot fully fill in the recesses in the surface of Al layer 204 so that there is a risk of having rather poor bonding characteristics.

### SUMMARY OF THE INVENTION

An object of the present invention is to provide a semiconductor device which has a bonding pad having excellent bonding characteristics with a simple manufacturing process.

A semiconductor device of the present invention is a semiconductor device provided with a bonding pad for connecting a bonding wire, wherein the bonding pad is formed on a flat surface, and a recess is created in a connection region of the bonding pad to which a bonding wire is connected.

According to the semiconductor device of the present invention, a recess is created in the connection region of the bonding pad to which a bonding wire is connected and, therefore, an interdiffusion region can be efficiently formed at the junction interface between the bonding pad and the bonding wire. Therefore, the bonding characteristics between the bonding pad and the bonding wire can be enhanced.

In addition, the bonding pad is formed on a flat surface and, therefore, it becomes unnecessary to form unevenness in the lower layer of the bonding pad and, correspondingly, the manufacturing process can be simplified. Furthermore, since it is unnecessary to form unevenness in the lower layer of the bonding pad, deterioration in the bonding characteristics due to poor step coverage of a bonding pad does not occur.

The foregoing and other objects, features, aspects and advantages of the present invention will become more apparent from the following detailed description of the present invention when taken in conjunction with the accompanying drawings.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross sectional view along line I-I of FIG. 2 schematically showing the configuration of a semiconductor device having a bonding pad according to the first embodiment of the present invention;

FIG. 2 is a plan view schematically showing the configuration of the semiconductor device having the bonding pad according to the first embodiment of the present invention;

FIG. 3 is a cross sectional view along line III-III of FIG. 4 schematically showing the configuration of a semiconductor device having a bonding pad according to the second embodiment of the present invention;

FIG. 4 is a plan view schematically showing the configuration of the semiconductor device having the bonding pad according to the second embodiment of the present invention;

FIG. 5 is a cross sectional view along line V-V of FIG. 6 schematically showing the configuration of a semiconductor device having a bonding pad according to the third embodiment of the present invention;

FIG. 6 is a plan view schematically showing the configuration of the semiconductor device having the bonding pad according to the third embodiment of the present invention;

FIG. 7 is a cross sectional view along line VII-VII of FIG. 8 schematically showing the configuration of a semiconductor device having a bonding pad according to the fourth embodiment of the present invention;

FIG. 8 is a plan view schematically showing the configuration of the semiconductor device having the bonding pad according to the fourth embodiment of the present invention;

FIG. 9 is a schematic cross sectional view showing the configuration of a bonding pad formed of a single conductive layer in a semiconductor device having a bonding pad according to the third embodiment of the present invention;

FIG. 10 is a schematic cross sectional view showing the configuration of a bonding pad formed of a single conductive layer in a semiconductor device having a bonding pad according to the fourth embodiment of the present invention;

FIG. 11 is a view for describing that recesses are holes according to the present invention;

FIG. 12 is a cross sectional view schematically showing the configuration of a semiconductor device having a bonding pad according to a prior art;

FIG. 13 is a plan view schematically showing the configuration of the semiconductor device having the bonding pad according to the prior art;

FIG. 14 is a plan view showing a region wherein a bonding pad and a ball portion are easily bonded to each other when pressed together;

FIGS. 15 to 18 are schematic cross sectional views showing, in the order of the steps, a manufacturing method for a semiconductor device having a bonding pad according to a prior art; and

FIG. 19 is a schematic cross sectional view for describing a problem caused by poor step coverage of a bonding pad.

### DESCRIPTION OF THE PREFERRED EMBODIMENTS

In the following, embodiments of the present invention are described in reference to the drawings.

(First Embodiment)

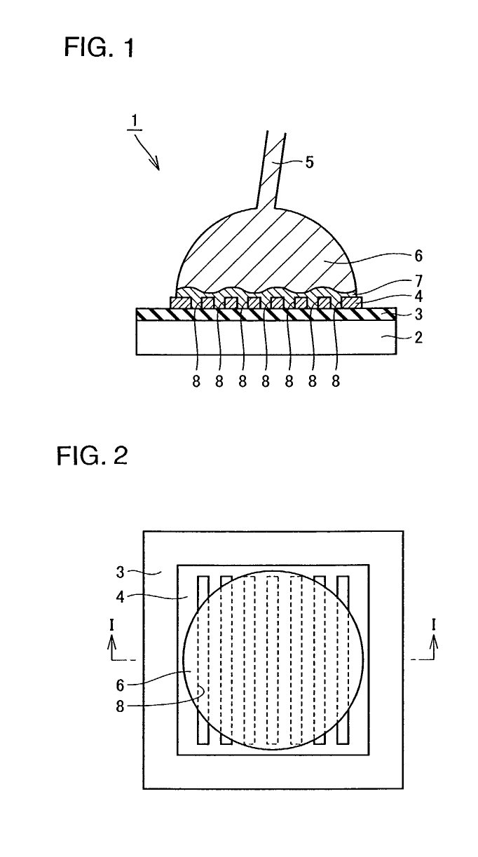

In reference to FIGS. 1 and 2, a semiconductor device 1 has a semiconductor element 2 made of silicon, or the like, an insulating layer 3 formed on the top surface of this semiconductor element 2, a bonding pad 4 formed on this insulating layer 3 and a gold wire 5 electrically connected to this bonding pad 4.

The tip of gold wire 5 that is to be connected to bonding pad 4 becomes a ball portion 6 formed by means of spark discharge, or the like. An interdiffusion region 7 is formed, by means of ultrasonic waves or heat, at the junction interface of this ball portion 6 with bonding pad 4. Thereby, gold wire 5 and bonding pad 4 are physically and electrically connected to each other.

A plurality of recesses 8 is created in the surface of this bonding pad 4 with which ball portion 6 makes a junction. Each recess 8 is a hole penetrating bonding pad 4 from the top surface through the bottom surface and is a slit in a trench form that extends in a predetermined direction.

In order to make a junction between bonding pad 4 and ball portion 6 of gold wire 5 according to the present embodiment, first, ball portion 6 is pressed from above by a capillary head against the top surface of bonding pad 4. Interdiffusion region 7 is formed under heat conditions of from 200° C. to 300° C. by utilizing intermetallic diffusion between ball portion 6 and bonding pad 4 and, thereby, thermo-compression bonding is carried out. Here, ultrasonic waves may be applied together with the thermo-compression bonding so that the intermetallic diffusion is accelerated.

According to the present embodiment, recesses 8 are created in a connection region of bonding pad 4 to which ball portion 6 is connected and, therefore, interdiffusion region 7 can be efficiently formed at the junction interface between bonding pad 4 and ball portion 6. This is because the greater is the frictional force between bonding pad 4 and ball portion 6 generated by ultrasonic waves provided at the time of wire bonding, the more efficiently interdiffusion region 7 is formed and the frictional force thereof becomes greater due to recesses 8. Since interdiffusion region 7 can be efficiently formed, the bonding characteristics between bonding pad 4 and ball portion 6 can be enhanced.

In addition, the surface of insulating layer 3 on which bonding pad 4 is formed is flat and unevenness is not implemented. Therefore, a process for forming unevenness in insulating layer 3 becomes unnecessary and, therefore, the manufacturing process can be simplified in comparison with the prior art. In addition, a pattern for recesses 8 may simply be added to the mask data for bonding pad 4 in order to create recesses 8 in bonding pad 4. Therefore, no extra step is added to the manufacturing process in order to create recesses 8 in bonding pad 4.

Furthermore, it is not necessary to form unevenness on the surface of insulating layer 3 that is the lower layer of bonding pad 4 and, therefore, deterioration in the bonding characteristics due to poor step coverage of bonding pad 4 does not occur.

(Second Embodiment)

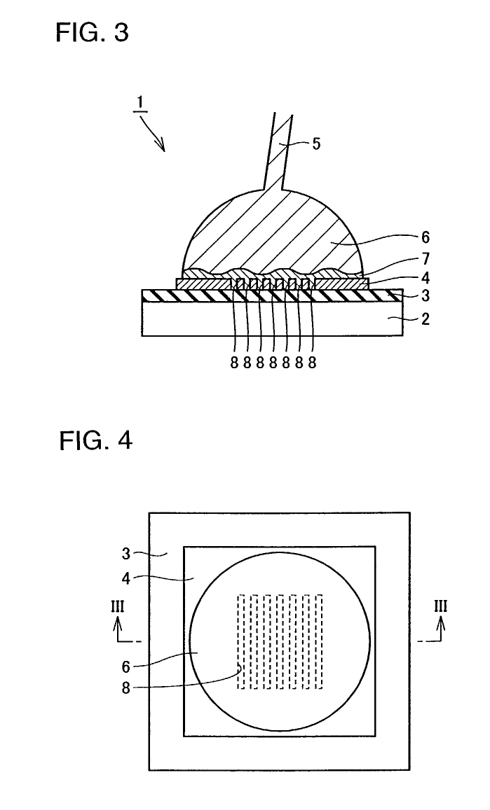

In reference to FIGS. 3 and 4, the configuration of the present embodiment differs from the configuration of the first embodiment in the form of recesses 8. Recesses 8 of the present embodiment are positioned only in the center portion of the junction region between bonding pad 4 and ball portion 6 wherein interdiffusion region 7, in particular, is not easily formed.

Here, the diameter of the junction portion between bonding pad 4 and ball portion 6 is assumed to be 80 μm, for example, and, then, the outer peripheral region wherein interdiffusion region 7 is easily formed is located in a diameter range of from 50 μm to 70 μm while the other regions (inner peripheral region in a diameter range of less than 50 μ,m and outermost peripheral region in a diameter range exceeding 70 μm) become regions wherein interdiffusion region 7 is not easily formed. Accordingly, when the diameter of the junction portion between bonding pad 4 and ball portion 6 is X, the outer peripheral region wherein interdiffusion region 7 is easily formed is located in a diameter range of from (50/80)X to (70/80)X while the other regions (inner peripheral region in a diameter range of less than (50/80)X and outermost peripheral region in a diameter range exceeding (70/80)X) become regions wherein interdiffusion region 7 is not easily formed.

Here, the other parts of the configuration are approximately the same as in the configuration of the above described first embodiment and, therefore, the same symbols are attached to the same members, of which the descriptions are omitted.

According to the present embodiment, recesses 8 are concentrated only to the center portion of the junction region between bonding pad 4 and ball portion 6. This center portion of the junction region is a region wherein interdiffusion region 7 is not easily created as described above. However, by creating recesses 8, the frictional force between bonding pad 4 and ball portion 6 becomes greater in the center portion of the junction region at the time of wire bonding so that interdiffusion region 7 become to be easily formed. Thereby, the bonding characteristics between bonding pad 4 and ball portion 6 in the center portion of the junction region can be improved and, therefore, bonding in the entirety of the junction region can be enhanced.

(Third Embodiment)

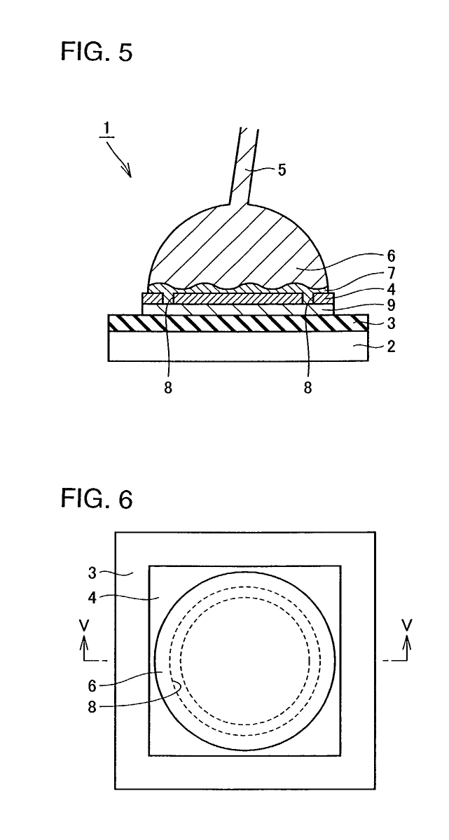

In reference to FIGS. 5 and 6, the configuration of the present embodiment differs from the configuration of the first embodiment in the points wherein the bonding pad is formed of a plurality of (for example, two layers) conductive layers 4 and 9 and wherein a recess 8 is in a circular trench form.

The bonding pad has a two-layered structure of conductive layer 9 formed on an insulating layer 3 and second conductive layer 4 formed on this conductive layer 9. Recess 8 in a circular trench form is created in this second conductive layer 4. This recess 8 is arranged in the outer peripheral region wherein compression bonding is easily carried out at the junction region between bonding pad 4 and ball portion 6 and, in addition, is a hole penetrating second conductive layer 4, from the top surface through the bottom surface.

Here, the other parts of the configuration are approximately the same as in the configuration of the above described first embodiment and, therefore, the same symbols are attached to the same members, of which the descriptions are omitted.

According to the present embodiment, recess 8 is created in the outer peripheral region wherein compressive bonding is easily carried out at the junction region between bonding pad 4 and 9 and ball portion 6. Therefore, interdiffusion region 7 is more easily formed in this outer peripheral region so that the bonding characteristics between bonding pad 4 and 9 and ball portion 6 can be further improved in this portion.

(Fourth Embodiment)

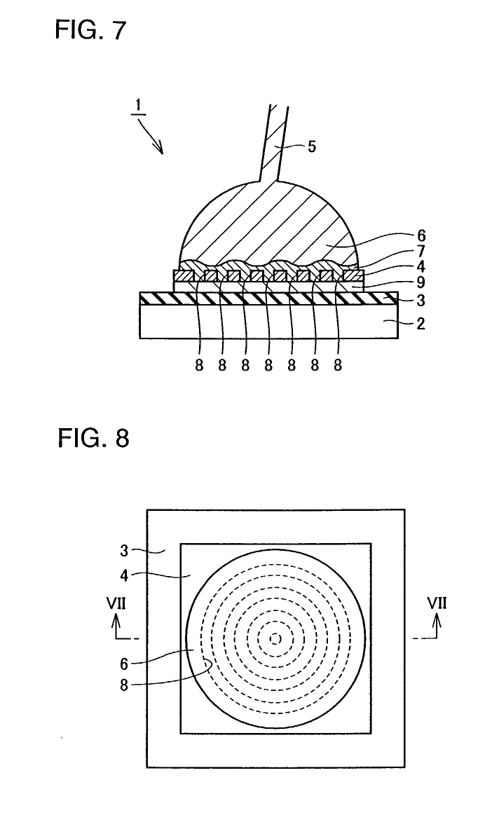

In reference to FIGS. 7 and 8, the configuration of the present embodiment differs from the configuration of the third embodiment in the point wherein recesses 8 in circular trench forms are created not only in the outer peripheral region wherein interdiffusion region 7 is easily formed at the junction region between bonding pad 4 and 9 and ball portion 6 but, also, in the inner peripheral region wherein interdiffusion region 7 is not easily formed. That is to say, respective recesses 8 in a plurality of circular trench forms having different diameters are arranged to share the same center.

Here, the other parts of the configuration are approximately the same as in the configuration of the above described third embodiment and, therefore, the same symbols are attached to the same members, of which the descriptions are omitted.

According to the present embodiment, recesses 8 are also created in the inner peripheral region wherein interdiffusion region 7 is not easily formed at the junction region between bonding pad 4 and 9 and ball portion 6. Therefore, interdiffusion region 7 can be easily formed in this inner peripheral region so that it becomes possible to improve the bonding characteristics between bonding pad 4 and 9 and ball portion 6.

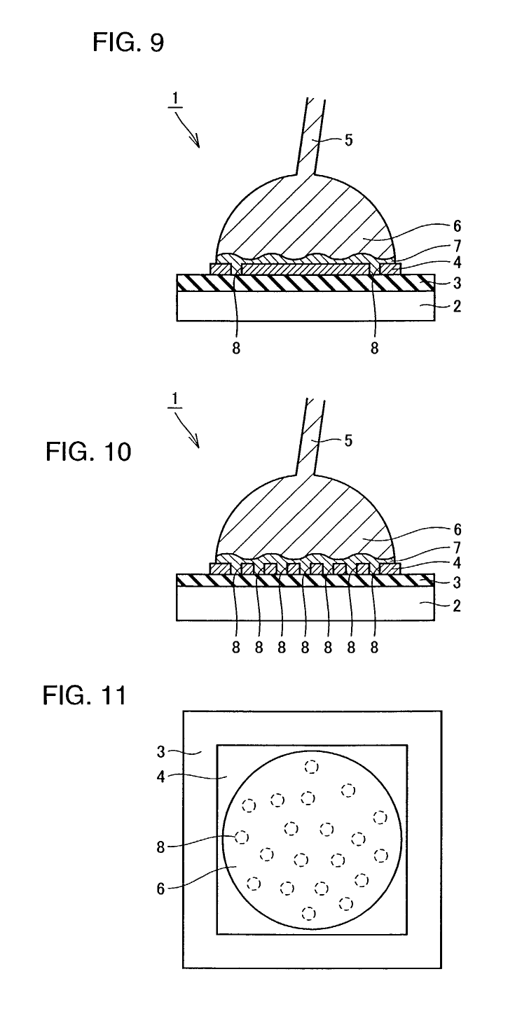

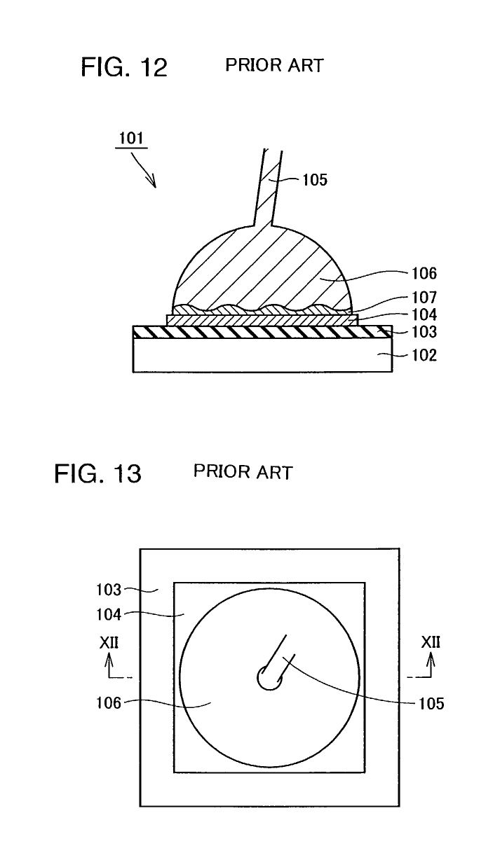

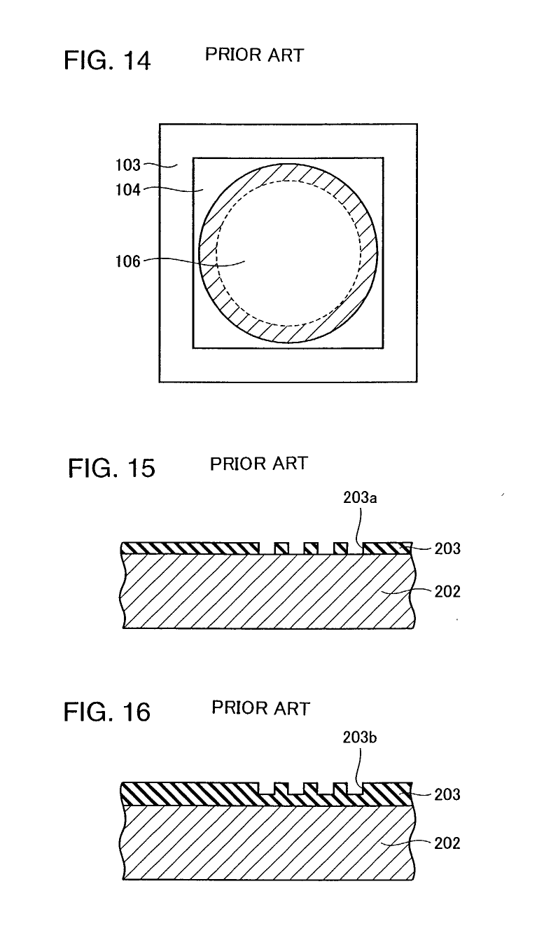

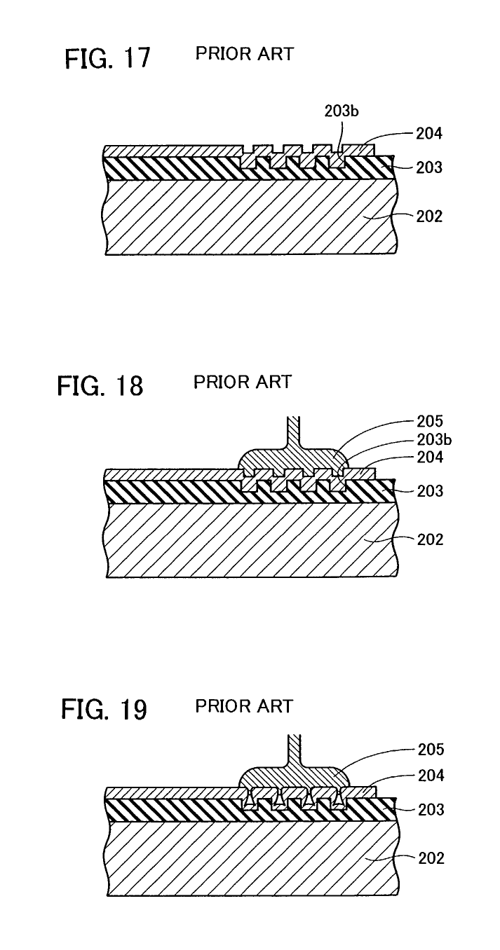

Here, though a case is described wherein bonding pad 4 and 9 has a structure wherein a plurality of conductive layers are layered in the third and fourth embodiments, the bonding pad may be formed of a single conductive layer 4 having recesses 8, as shown in the cross sectional views of FIGS. 9 and 10.

In addition, though recesses 8 in trench forms in a plan view are described in the first to fourth embodiments, they may be holes, as shown in the plan view of FIG. 11, and may be in any form as long as unevenness can be implemented on the surface of the bonding pad.

The recesses in the above described semiconductor device are holes penetrating the bonding pad from the top surface through the bottom surface. Thereby, the depth of the recesses can be increased so that the frictional force between the bonding pad and the bonding wire can be increased at the time of wire bonding. Accordingly, the interdiffusion region can be more efficiently formed at the junction interface between the bonding pad and the bonding wire.

The recesses are in trench forms in the above described semiconductor device. In the case that the recesses are in trench forms in such a manner, the same effects as are described above can be gained.

In the above described semiconductor device, the bonding pad has a configuration wherein, at least, two conductive layers are layered and the above described recesses are created in the top conductive layer from among the above described layered conductive layers. The present invention can be applied to a bonding pad having such a configuration wherein conductive layers are laminated.

In the above described semiconductor device, the above described holes are created in circular trench forms in the outer peripheral region wherein the above described bonding wire is easily bonded to the above described bonding pad in the connection region. Thereby, the bonding characteristics can be further enhanced.

In the above described semiconductor device, the recesses are created in the inner peripheral region wherein the bonding wire is not easily bonded to the bonding pad in the connection region. Thereby, the bonding characteristics of the inner peripheral region can be improved.

The embodiments disclosed herein should be considered as illustrative from all points of view and are not limitative. The scope of the present invention is defined not by the above description but, rather, by the claims and is intended to include meanings equivalent to the claims and all modifications within the scope.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising a bonding pad for connecting a bonding wire, wherein
said bonding pad is formed on a flat surface, and a recess is created in a connection region of said bonding pad to which said bonding wire is connected.

2. The semiconductor device according to claim 1, wherein said recess is a hole penetrating said bonding pad from an upper surface to a lower surface thereof.

3. The semiconductor device according to claim 1, wherein said recess is of a trench form.

4. The semiconductor device according to claim 1, wherein said bonding pad has a configuration that at least two conductive layers are laminated, so that said recess is created in the uppermost conductive layer among the laminated conductive layers.

5. The semiconductor device according to claim 1, wherein said hole is created in a circular trench form in an outer peripheral region, in which said bonding wire easily makes a close contact with said bonding pad, in said connection region.

6. The semiconductor device according to claim 1, wherein said recess is created in an inner peripheral region, in which said bonding wire does not easily make a close contact with said bonding pad, in said connection region.
